(19) United States
(12) Patent Application Publication
(10) Pub. No.: US 2013/0263907 A1
(43) Pub. Date: Oct. 10, 2013

(54) THERMOELECTRIC CONVERSION MATERIAL, THERMOELECTRIC CONVERSION DEVICE, AND THERMOELECTRIC CONVERSION MODULE

(71) Applicant: HITACHI, LTD., Tokyo (JP)

(72) Inventors: Shin YABUUCHI, Tokyo (JP); Masakuni OKAMOTO, Tokyo (JP); Jun HAYAKAWA, Tokyo (JP); Yosuke KUROSAKI, Tokyo (JP); Akinori NISHIDE, Tokyo (JP)

(73) Assignee: HITACHI, LTD., Tokyo (JP)

(21) Appl. No.: 13/802,871

(22) Filed: Mar. 14, 2013

(30) Foreign Application Priority Data
Apr. 10, 2012 (JP) 2012-089104

(51) Int. Cl. H01L 35/16; H01L 35/04

(52) U.S. Cl. CPC H01L 35/16; H01L 35/04
USPC 136/238; 252/519.14

(57) ABSTRACT

Provided is a p-type thermoelectric conversion material achieving a low environment load and low costs and having high efficiency. A thermoelectric conversion device is constituted by raw materials existing in a great amount in nature by using Fe and S as main components. Further, since FeS₂ of a pyrite structure has a d orbit derived from Fe in a valence band and a high state density, high performance as the thermoelectric conversion device is implemented by adding an addition element to this material system to express a p-type semiconductor characteristic.

### CLAIM OF PRIORITY

The present application claims priority from Japanese patent application JP 2012-089104 filed on Apr. 10, 2012 the content of which is hereby incorporated by reference into this application.

### FIELD OF THE INVENTION

The present invention relates to a thermoelectric conversion material, a thermoelectric conversion device, and a thermoelectric conversion module.

### BACKGROUND OF THE INVENTION

Currently, there is a demand for actively utilizing natural energy such as sunlight, wind power, and geothermal heat, which is not accompanied by generation of greenhouse effect gas without depending on fossil fuel due to the environment and energy problem or resource depletion. Sunlight generation or wind power generation having a low environment load is spreading, and an effective utilization of heat energy is receiving attention. In practice, heat energy is emitted in a great quantity from an incineration plant, a subway, or an electric power substation around us. A temperature of waste heat emitted from the incineration plant or the like is 300 to 600° C., which is high, and a temperature of waste heat from the subway or the electric power substation is 40 to 80° C., which is low. The total quantity of waste heat energy having the relatively low temperature (200° C. or less) is great, but an effective energy recovery technology is not established. A thermoelectric conversion device has been known from old times as one of utilization methods of waste heat energy. In thermoelectric conversion, electricity is directly generated due to a temperature difference without a driving portion, and thus a loss is small as compared to a method of generating electricity by generating steam from heat of thermal power or atomic power to rotate a turbine. Further, since wastes are not generated, the thermoelectric conversion is environmentally friendly. Further, if a voltage is applied to both ends of a thermoelectric conversion device, a temperature difference occurs, and a Seebeck effect of the thermoelectric conversion, which was found in 1821, is obtained, but there is a problem in that conversion efficiency is low. Currently, Bi₂Te₃ is commercialized as a thermoelectric conversion material having relatively good efficiency at a temperature of 200° C. or less. Further, the thermoelectric conversion material such as Bi—Te, which has good conversion efficiency at around room temperature, is a Peltier device, and can be used as a cooling device and can be used in a cooling apparatus having a small environment load which does not use a cooling medium.

Performance of the thermoelectric conversion material is evaluated by a dimensionless performance index (ZT).

$$\begin{matrix}[ Equation 1 ] & \\ Z = \frac{σ {S}^{2}}{κ} & ( 1 )\end{matrix}$$

Herein, σ is electric conductivity, S is a Seebeck coefficient, κ is thermal conductivity, and T is a temperature. A unit of Z itself is K⁻¹. FIG. 6 illustrates a relationship between thermoelectric conversion efficiency and a temperature. Carnot efficiency refers to theoretical upper limit efficiency. In general, since the higher ZT is, the better performance is, a material having high Seebeck coefficient and electric conductivity and low thermal conductivity based on Equation (1) is preferable as a thermoelectric conversion material. In both of p-type and n-type Bi−Te-based materials, performance index ZT>1 and thus conversion efficiency is high, but since Bi and Te are both costly and Te has very strong toxicity, there is a demand for replacing Bi₂Te₃ with a high efficiency thermoelectric conversion material for mass production, and a reduction in cost and environment load.

A thermoelectric conversion material including Fe₂VAl that is a Full-Heusler alloy as a base material has been reported as a material system having a low environment load in Japanese Patent Application Laid-Open (JP-A) No. 2004-253618. Fe₂VAl is constituted by elements having a low environment load and a relatively low cost, such as Fe, V, and Al, and toxic rare metal is not used unlike the Bi—Te-based material, and thus Fe₂VAl is a material system having industrial applicable value. However, a thermoelectric conversion characteristic surpassing that of the Bi—Te system at the temperature range of 200° C. or less is not obtained, and thus further researches and developments subsequently are needed.

Further, a CdI₂ type material having a laminate structure including particularly Ti has been reported as a thermoelectric material having excellent conversion efficiency in JP-A-2002-270907. JP-A-2002-270907 shows a material having the same structure as a crystal structure of TiS₂ and high thermoelectric conversion efficiency at the temperature range around room temperature, which are results from an n type, but does not show a p-type material system having good efficiency. Accordingly, there is a demand for a material system having a low environment load and low costs, exhibiting a p type and having high thermoelectric conversion efficiency.

Further, sulfides of transition metal such as Fe or Ni have been reported as a thermoelectric conversion material, which enables a low environment load and a reduction in cost, in IEEE 22nd International Conference on Thermoelectrics pp. 376-379 (2003). However, since a kind, concentration dependency, or a carrier density of an element doped in sulfides of transition metal is not controlled in IEEE 22nd International Conference on Thermoelectrics pp. 376-379 (2003), an optimum doping element needs to be selected and the carrier density needs to be controlled in order to exhibit a high thermoelectric conversion characteristic.

### SUMMARY OF THE INVENTION

Henceforth, it is considered that environment and energy problems become more important and transition to a clean power generation system not depending on fossil fuel is performed. Above all, there is a need to utilize an energy source rarely used until now, such as geothermal heat or waste heat. However, a thermoelectric conversion device using toxic rare metal, such as a Bi—Te system, commercialized as a thermoelectric conversion material having relatively low temperatures (200° C. or less), cannot be cheaply and stably provided to the market in a great amount, and thus a possibility of extensively spreading the thermoelectric conversion element is generally low. Further, in the material system described in JP-A-2004-253618, JP-A-2002-270907, or IEEE 22nd International Conference on Thermoelectrics 376 (2003), it is difficult to allow a low environment load, a reduction in cost, a high Seebeck coefficient, and a high p-type carrier density to be compatible.

The present invention has been made in an effort to provide a p-type thermoelectric conversion material in which a low environment load and a reduction in cost are feasible and a high Seebeck coefficient and a high carrier density are compatible, and a thermoelectric conversion device and a thermoelectric conversion module having high conversion efficiency.

An embodiment of the present invention for accomplishing the object provides a thermoelectric conversion material having a pyrite structure, in which a composition is represented by Fe₁₋ₓMₓS_{2-y}T_{y}, element M is at least one kind of element selected from V, Cr, Mn, Zr, Nb, Mo, Hf, Ta, and W, element T is at least one kind of element selected from B, C, Al, Si, Ge, Sn, N, O, P, and Bi, x and y that are total composition values of the individual elements are each in the range of 0<x<0.5 and 0<y<1, and a conductive type is a p type.

Further, another embodiment of the present invention provides a thermoelectric conversion device including a thermoelectric conversion material layer, and a first upper electrode and a first lower electrode installed by interposing the thermoelectric conversion material layer therebetween, in which the thermoelectric conversion material layer is a p-type material layer having a pyrite structure whose composition is represented by FeS₂, and including at least a portion of Fe and S which is substituted by an addition element.

Further, yet another embodiment of the present invention provides a thermoelectric conversion module where a plurality of p-type thermoelectric conversion material layers spaced apart from each other and a plurality of n-type thermoelectric conversion material layers spaced apart from each other, which are arranged to be adjacent to each other, on an insulating substrate are connected in series, in which the p-type thermoelectric conversion material layer is a p-type material layer having a pyrite structure whose composition is represented by FeS₂ and including at least a portion of Fe and S which is substituted by an addition element.

There may be provided a p-type thermoelectric conversion material in which a low environment load and a reduction in cost are feasible and a high Seebeck coefficient and a high carrier density are compatible, and a thermoelectric conversion device and a thermoelectric conversion module having high conversion efficiency.

### BRIEF DESCRIPTION OF THE DRAWINGS

FIG. 1 is a conceptual view for illustrating a crystal structure of pyrite (FeS₂);

FIG. 2 is a band diagram of pyrite (FeS₂);

FIG. 3 is a view illustrating chemical potential dependency (upper drawing) of a state density and chemical potential dependency (lower drawing) of a Seebeck coefficient of pyrite (FeS₂);

FIG. 4A is a view illustrating temperature dependency of a Seebeck coefficient of pyrite (FeS₂) that is a thermoelectric conversion material according to an embodiment of the present invention;

FIG. 4B is a view illustrating hole carrier density dependency of the Seebeck coefficient of pyrite (FeS₂) that is the thermoelectric conversion material according to the embodiment of the present invention;

FIG. 5A is a view illustrating a relationship between the Seebeck coefficient and a change in valence electron number of pyrite (FeS₂) that is the thermoelectric conversion material according to the embodiment of the present invention;

FIG. 5B is a view illustrating a relationship between the Seebeck coefficient and an addition amount of pyrite (FeS₂) that is the thermoelectric conversion material according to the embodiment of the present invention;

FIG. 5C is a view illustrating a relationship between the Seebeck coefficient and the addition amount of pyrite (FeS₂) that is the thermoelectric conversion material according to the embodiment of the present invention;

FIG. 6 is a view illustrating a relationship between thermoelectric conversion efficiency and a temperature;

FIG. 7A is a schematic cross-sectional view illustrating an example of a thermoelectric conversion device according to a second embodiment;

FIG. 7B is a schematic cross-sectional view illustrating another example of the thermoelectric conversion device according to the second embodiment;

FIG. 8A is a schematic whole perspective view (some portions are omitted) illustrating an example of a thermoelectric conversion module according to a third embodiment; and

FIG. 8B is a schematic cross-sectional view illustrating another example of the thermoelectric conversion module according to the third embodiment.

### DETAILED DESCRIPTION OF THE PREFERRED EMBODIMENTS

The present inventors examined a material system in which a low environment load, a reduction in cost, a high Seebeck coefficient, and a high p-type carrier density can be compatible. Hereinafter, the results and the obtained opinions will be described.

High thermoelectromotive force depends on an electron state of a material, and a material having a rapid change in state density around a Fermi level is preferable. Since the material having the large change in state density needs to be in a localized electron state, a material system where electrons at a d orbit contribute to an electron state around the Fermi level, such as transition metal, becomes a candidate.

Examples of cheap and non-toxic transition metal may include iron (Fe). If the material system has the material system where a state derived from 3d of Fe is around the Fermi level as a mother phase, a large amount of earth-crust deposits exists, and it is possible to manufacture the thermoelectric conversion material having a low environment load. Accordingly, FeS₂ of the pyrite structure was conceived.

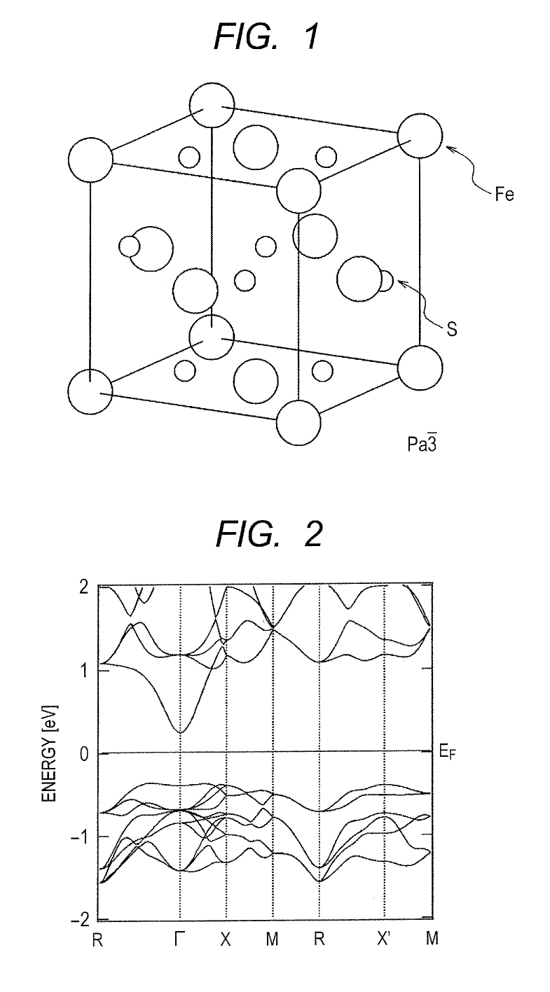

FIG. 1 illustrates a crystal structure of pyrite. In addition to FeS₂, AuSb₂, CaC₂, CoS₂, MnS₂, NiS₂, NiSe₂, OsS₂, OsTe₂, PdAs2, PtAs₂, PtBi2, RhSe₂, RuS₂, and the like are known as the compound of the pyrite structure. Accordingly, substitution of Fe and transition metal such as Co, Mn, and Ni is feasible, and it can be expected that an occupying number of a band (d-band) derived from the d orbit is modulated by doping an element having a valence electron number that is different from that of Fe.

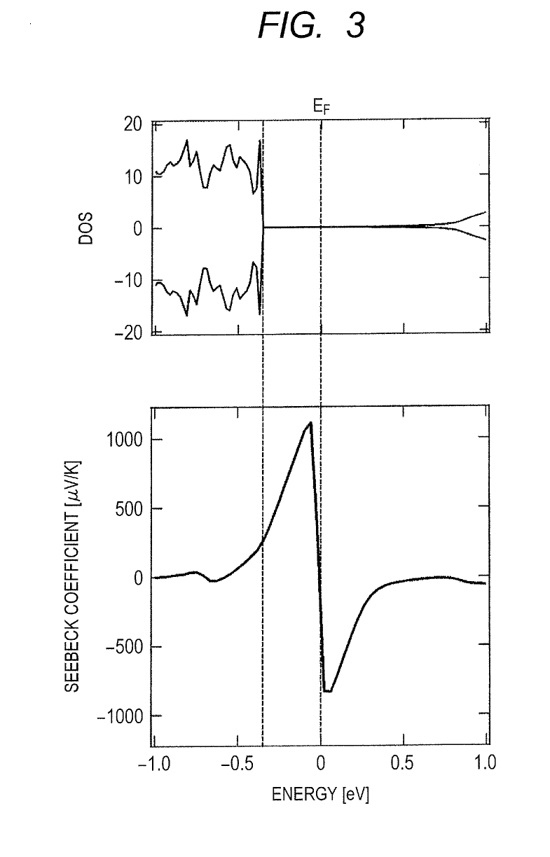

FIG. 2 illustrates a band structure of FeS₂ of the pyrite structure obtained by a first principle calculation. As illustrated in FIG. 2, a portion (vicinity portion) around a top of a valance band has a flat band structure. This corresponds to an electron state derived from a 3d orbit of Fe, and a localization property is stronger than that of an s orbit or a p orbit, and thus the flat band structure is obtained. An upper drawing of FIG. 3 illustrates a relationship between a state density (DOS) of FeS₂ of the pyrite structure obtained by the first principle calculation and energy. As illustrated in the upper drawing of FIG. 3, the state density of the top of the valance band is very rapidly changed as compared to a conductance band. The material system where the state density of the valance band is rapidly changed, like FeS₂ of the pyrite structure, can implement high efficiency as the p-type thermoelectric conversion device. Further, since the electron state of the system strongly depends on the crystal structure thereof, the pyrite structure having the flat electron state is very important.

Next, a lower drawing of FIG. 3 illustrates a change in Seebeck coefficient at room temperature when a chemical potential is changed by the first principle calculation in order to examine a possibility of modulation of the Seebeck coefficient by controlling of the Fermi level by thermoelectromotive force. Further, as illustrated in Equation (1), the square of the Seebeck coefficient exerts an effect for Z, which is effective in improving thermoelectric conversion efficiency. As illustrated in the lower drawing of FIG. 3, the carrier density is changed by doping and the like, a p-type conductance characteristic is exhibited as the Fermi level approaches the vicinity of the valance band, and the Seebeck coefficient has a positive value. In addition, in the lower drawing of FIG. 3, the Seebeck coefficient has a value more than maximum 1,000 μV/K and about 250 μV/K even in energy around the top of the valance band. This implies a possibility of exhibiting the high Seebeck coefficient even at the very high hole carrier density, and thus the material system is a material system where high electric conductivity and the high Seebeck coefficient can be compatible due to the high carrier density.

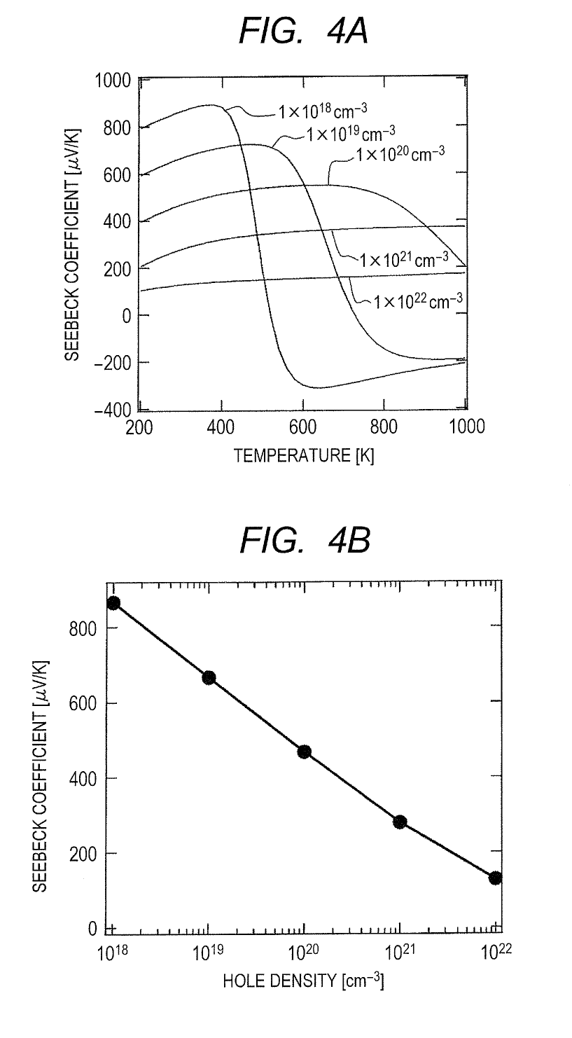

Temperature dependency of the Seebeck coefficient at each hole carrier density obtained by calculation is illustrated in FIG. 4A, and hole carrier density dependency of the Seebeck coefficient at room temperature is illustrated in FIG. 4B. In FIG. 4B, it can be seen that the high Seebeck coefficient of more than 800 μV/K at the hole carrier density of 1×10¹⁸ cm³ and room temperature is obtained, and the high Seebeck coefficient of 300 μV/K even at the hole carrier density of 1×10²¹ cm³ is obtained. Further, if the carrier density is 1×10²² cm⁻³ or more, it is difficult to obtain the high Seebeck coefficient of 100 μV/K or more, and thus the carrier density needs to be 1×10²² cm⁻³ or less in order to obtain the high Seebeck coefficient.

Appropriate doping needs to be performed in order to control the carrier density to the aforementioned carrier density, and a valence electron number density (VEC) can be used as a design guideline. The total valence electron number VEC in a stoichiometric composition of FeS₂ is obtained from the valence electron number n_{Fe}=8 of Fe and the valence electron number nₛ=6 of S so that VEC=n_{Fe}+2nₛ=20. Further, it is possible to control the VEC by forming Fe₁₋ₓMₓS_{2-y}T_{y} into which M and T that are elements different from Fe and S are introduced. The valence electron number of each element is described in Table 1.

TABLE 1

| Transition element M | | | | | | | | | | Nonmagnetic element T | | | | |
|---|---|---|---|---|---|---|---|---|---|---|---|---|---|---|
| | Valence electron number | | | | | | | | | | | | | |
| | 3 | 4 | 5 | 6 | 7 | 8 | 9 | 10 | 11 | 12 | 3 | 4 | 5 | 6 |
| Element | Sc | Ti | V | Cr | Mn | Fe | Co | Ni | Cu | Zn | B | C | N | O |
| | Y | Zr | Nb | Mo | Re | Ru | Rh | Pd | Ag | Cd | Al | Si | P | S |
| | [symbol] | Hf | Ta | W | | Os | Ir | Pt | Au | Hg | Ga | Ge | As | Se |
| | | | | | | | | | | | In | Sn | Sb | Te |
| | | | | | | | | | | | Tl | Pb | Bi | |

Ln: La, Ce, Pr, Nd, Pm, Sm, Gd, Tb, Dy, Ho, Er, Tm, Yb, Lu

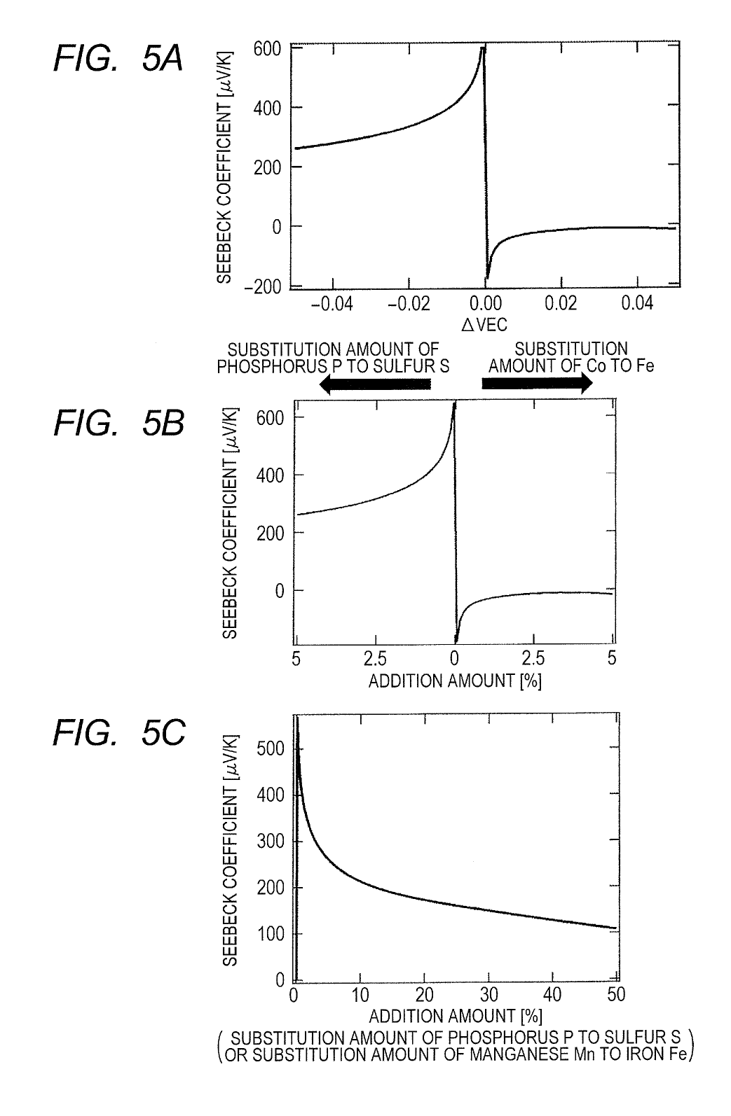

It is possible to express a p-type property by setting the VEC to 20 or less. A relationship between a change in VEC (ΔVEC) and the Seebeck coefficient at room temperature obtained by the calculation is illustrated in FIG. 5A, and a relationship between a doping amount of P or Co to FeS₂ and the Seebeck coefficient is illustrated in FIGS. 5B and 5C. In FIGS. 5A to 5C, it can be seen that the material system having the positive Seebeck coefficient can be manufactured by reducing the VEC (corresponding to an increase in substitution amount of phosphorus P to sulfur S). Further, if the VEC is changed by 1 or more, it is difficult to set the carrier density to 1×10²² cm³ or less at which the high Seebeck coefficient can be obtained. In addition, it is preferable that x and y of Fe₁₋ₓMₓS_{2-y}T_{y} be in the range of 0<x<0.5 and 0<y<1 (each addition amount is more than 0 and less than 50%) because it is difficult to maintain the pyrite structure if the amount of Fe, which is a mother phase, is larger than that of S.

Next, elements to be added to these pyrites will be described. It is possible to control the Fermi level by adjusting the VEC as described above. In Table 1, V, Cr, and Mn that are 3d transition metal have the valence electron number that is smaller than that of Fe, and thus are effective to substitute Fe and reduce the VEC. It is known that MnS₂ has the pyrite structure, and thus Mn is easily substituted by Fe. Since a difference in valence electron number from Fe is increased in order of Mn, Cr, and V, the smaller the difference in valence electron number of the element from Fe is, the better the element is. In Table 1, likewise, Zr, Nb, and Mo that are 4d transition metals have the valence electron number that is smaller than that of Fe, and thus are effective in reducing the VEC.

Further, since a difference in valence electron number from Fe is increased in order of Mo, Nb, and Zr, the smaller the difference in valence electron number of the element from Fe is, the better the element is. In addition, 4d transition metals have masses that are largely different from that of Fe, and thus is effective in controlling the VEC and reducing thermal conductivity. In Table 1, likewise, Hf, Ta, and W that are 5d transition metals have the valence electron number that is smaller than that of Fe, and thus are effective in reducing the VEC. Further, since a difference in valence electron number from Fe is increased in order of W, Ta, and Hf, the smaller the difference in valence electron number of the element from Fe is, the better the element is. In addition, the 5d transition metals have masses that are largely different from that of Fe, and thus has an effect of reducing thermal conductivity, which is higher than the effect of the 4d transition metal. Next, doping of a typical element will be described. FeS₂ can control the VEC by substituting S as well as Fe. Among the typical elements, examples of the relatively cheap and non-toxic or low-toxic elements may include B, C, N, O, Al, Si, P, Ge, and Sn. Among the examples, B, C, N, and O can control the VEC according to the valence electron number, but have atomic radiuses that are largely different from that of S, and thus cannot be added in a great amount. However, B, C, N, and O are light elements having the masses that are largely different from that of S, and thus can be expected to have an effect of inhibiting lattice thermal conductivity. Since a difference in valence electron number from S is increased in order of P, Si, and Al, the smaller the difference in valence electron number of the element from S is, the better the element is. Sn has the mass that is larger than that of S, and thus can be expected to have an effect of reducing lattice thermal conductivity. Further, Bi is a relatively rare material, but is the heaviest element in Table 1 and has the valence electron number that is different from that of S by only 1, and thus is effective to control the VEC and reduce lattice thermal conductivity. Further, since pyrite has low thermal stability at high temperatures, there is a high possibility of decomposing the pyrite by FeS and S gases of the NiAs structure at 750° C. or more, and thus it is preferable to use the pyrite under an environment of 700° C. or less. In addition, it is preferable to use the pyrite at room temperature or more in view of thermoelectric conversion efficiency.

The crystal structure of the thermoelectric conversion material having the pyrite structure may be easily confirmed by an X-ray diffraction (XRD). Further, a lattice image may be observed by an electron microscope such as a TEM (transmission electron microscope), or a monocrystal or a polycrystal crystal structure may be confirmed from a spot type pattern or a ring type pattern in an electronic beam diffraction phase. The composition distribution may be confirmed by using an EPMA (electron probe microanalyzer) such as an EDX (energy dispersive X-ray spectroscopy), a SIMS (secondary ionization mass spectrometer), or methods such as X-ray photoelectron spectroscopy and ICP (inductively coupled plasma). In addition, information on state density of the material may be confirmed by a UV photoelectron spectroscopy, the X-ray photoelectron spectroscopy, or the like. The electric conductivity and the carrier density may be confirmed by electric measurement and hole effect measurement using a four-point-probe method. The Seebeck coefficient may be confirmed by setting a temperature difference at both ends of a sample and measuring a voltage difference between both ends. Thermal conductivity may be confirmed by a laser flash method.

The present invention is deduced from the examination results and new opinions obtained therefrom, and is characterized in that an excellent thermoelectric conversion characteristic is expressed by performing appropriate doping on the compound having the pyrite structure to introduce elements having different valence electron numbers and masses, and controlling the carrier density, electric conductivity, and thermal conductivity. Specific examples thereof include a material system where FeS₂ of the pyrite structure having Fe and S as main components is used as a main component.

According to the present invention, it is possible to change an electron occupying number of a d-band, modulate an electron state at a Fermi level, and adjust a carrier type and carrier density according to the purpose by adding elements having different valence electron numbers by doping and controlling a valence electron number of a compound. Further, it is possible to reduce thermal conductivity by doping a lighter element and a heavier element than Fe and S.

Hereinafter, the embodiments will be described.

### First Embodiment

A first embodiment illustrates an example of sample preparation. Herein, the Preparation Example is just an example, and, of course, is not limited to the corresponding preparation condition.

### Sample Preparation Example 1

After metal Fe powder, Mn powder, and S powder having purity of 99.9% were mixed at a compositional ratio of 99:1:200 and the alloy was prepared by a known mechanical alloying method, if the VEC was calculated from the prepared composition Fe_{0.99}Mn_{0.01}S₂, the VEC became 19.99 (Mn addition amount: 1%).

### Sample Preparation Example 2

Metal Fe powder, Mn powder, and S powder having purity of 99.9% were mixed at a compositional ratio of 7:3:20, put into the quartz tube, and subjected to heat treatment under a vacuum atmosphere at 700° C. for 24 hours, and thereafter, the sample was pulverized by using the ball mill. The structure was analyzed by performing X-ray diffraction of the powder sample, and as a result, the structure was the pyrite structure. If the VEC was calculated from the powder sample of Fe_{0.7}Mn_{0.3}S₂ by the aforementioned process, the VEC became 19.7 (Mn addition amount: 30%).

### Sample Preparation Example 3

Metal Fe powder, P powder, and S powder having purity of 99.9% were mixed at a compositional ratio of 100:1:199, put into the quartz tube, and subjected to heat treatment under a vacuum atmosphere at 700° C. for 24 hours, and thereafter, the sample was pulverized by using the ball mill. The structure was analyzed by performing X-ray diffraction of the powder sample, and as a result, the structure was the pyrite structure. If the VEC was calculated from the powder sample of FeS_{1.99}P_{0.01} by the aforementioned process, the VEC became 19.99 (P addition amount: 0.05%).

### Sample Preparation Example 4

Fe_{0.99}V_{0.01}S₂, Fe_{0.99}Cr_{0.01}S₂, Fe_{0.99}Zr_{0.01}S₂, Fe_{0.99}Mo_{0.01}S₂, Fe_{0.99}Hf_{0.01}S₂, Fe_{0.99}Ta_{0.01}S₂, and Fe_{0.99}W_{0.01}S₂ were prepared by substituting Fe by V, Cr, Zr, Mo, Hf, Ta, and W by the same method as Sample Preparation Example 2. If the VECs were calculated from the aforementioned compositions, the VECs became 19.97, 19.98, 19.96, 19.98, 19.96, 19.97, and 19.98 (each addition amount: 1%).

### Sample Preparation Example 5

The thin film having the film thickness of about 300 nm was prepared on the Si substrate having the thermal oxide film by performing sputtering using the target where Fe and S were mixed at a composition ratio of 1:2, and subjected to heat treatment under a nitrogen atmosphere at the condition of 600° C. for 1 hour. The structure was analyzed by performing X-ray diffraction of the thin film, and as a result, the peak of the pyrite structure could be observed.

### Sample Measurement Example 1

The temperature of the samples prepared in Preparation Examples 1 and 2 were made different from room temperature by 20° C. and the Seebeck coefficient was measured. As a result, the high Seebeck coefficients of 350 μV/K and 100 μV/K were obtained. Accordingly, it could be confirmed that in the material system, the Seebeck coefficient was modulated and the high thermoelectromotive force as the p type was ensured by preparing the sample having the doping amount changed by the method of the present Example 1 to change the VEC. Further, thermal conductivities were each 10 mW/Kcm and 15 mW/Kcm.

The sample preparation method may be a vacuum deposition method such as molecular beam epitaxy other than the present embodiment, or chemical vapor deposition using a transition metal complex or the like may be used. Further, the sample preparation method may be a method of heating sulfur to vaporize sulfur, sending the vaporized sulfur to the reaction room where the iron plate was charged with carrier gas that was inert gas such as argon, and reacting the vaporized sulfur with the iron plate.

According to the present embodiment, an electron occupying number of a d-band may be changed and an electron state at a Fermi level may be modulated by adding elements having different valence electron numbers by doping and controlling a valence electron number of a compound, thus implementing high thermoelectromotive force. Further, it is possible to significantly reduce a cost as compared to the Bi—Te system by combining cheap materials with few anxieties of depletion.

As described above, according to the present embodiment, it is possible to provide a p-type thermoelectric conversion material where a low environment load and a reduction in cost are feasible and a high Seebeck coefficient and a high carrier density can be compatible.

### Second Embodiment

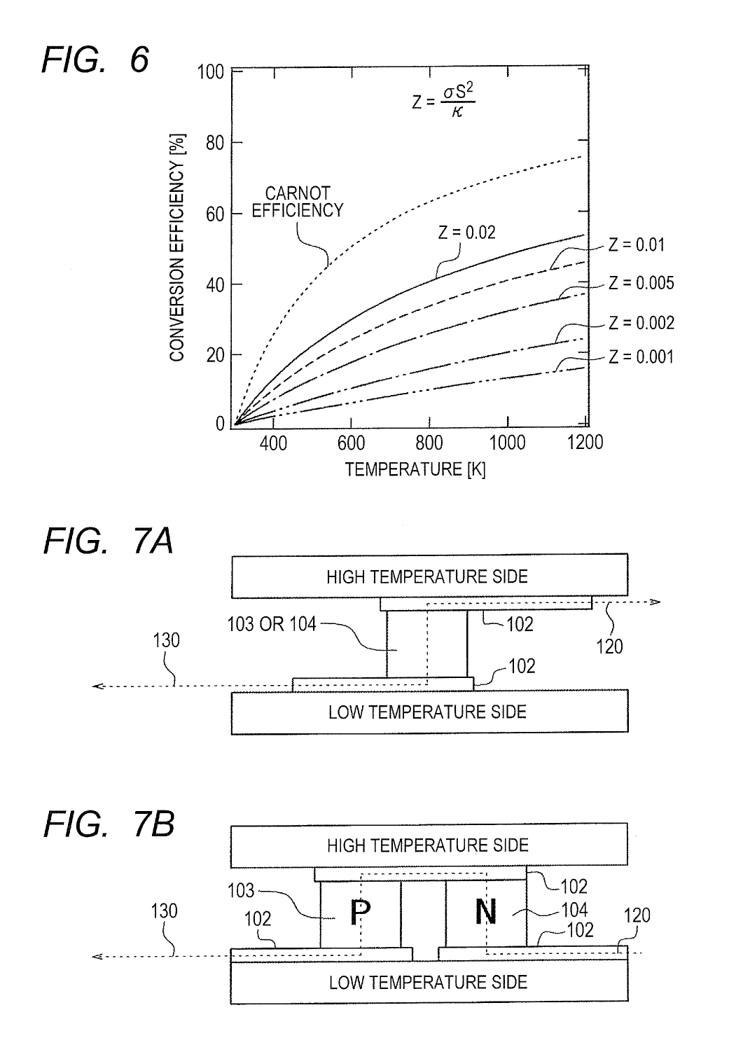

A second embodiment will be described by using FIGS. 7A and 7B. Further, a matter described in the first embodiment 1 but not described in the present embodiment can be applied to the present embodiment unless there is an unavoidable reason. FIGS. 7A and 7B are examples of a whole drawing of a thermoelectric conversion device, FIG. 7A illustrates a constitution in the case where an n-type semiconductor or a p-type semiconductor is used as the thermoelectric conversion device, and FIG. 7B illustrates a constitution in the case where both the n-type semiconductor and the p-type semiconductor are used as the thermoelectric conversion device. The p-type semiconductor device was prepared by substituting a portion of Fe by Mn or the like in FeS₂ of the pyrite structure by using the method of the first embodiment. Known TiS₂ (not added) may be used as the n-type semiconductor, but the n-type semiconductor is not limited thereto.

As illustrated in FIG. 7A, in the structure of the thermoelectric conversion device where electrodes 102 are installed on a counter surface of a p-type semiconductor layer 103 or an n-type semiconductor layer 104, in the case where a temperature difference arises between the electrode 102 of the thermoelectric conversion device by using the p-type semiconductor layer 103, a current flow direction 130 is a direction from a high temperature side to a low temperature side. Meanwhile, in the case where the n-type semiconductor layer 104 is used, a current flow direction 120 is a direction from the low temperature side to the high temperature side.

As illustrated in FIG. 7B, in a thermoelectric conversion device having a n-type structure where upper portions of the p-type semiconductor layer 103 and the n-type semiconductor layer 104 are connected to the electrodes 102 and the electrodes 102 are each connected to each of lower portions, when the upper electrode 102 is set as the high temperature side, a current flows from the low temperature side to the high temperature side in the n-type semiconductor layer, the current flows from the high temperature side to the low temperature side in the p-type semiconductor layer, and flow directions 120 and 130 of the current may be identical.

In the structures illustrated in FIG. 7A (the case of the p-type semiconductor layer) and FIG. 7B, in the case where the hole carrier density is 1×10¹⁹ cm⁻¹, thermoelectric conversion efficiency could be increased at about room temperature (<)200 C°) to about three times thermoelectric conversion efficiency of the thermoelectric conversion device using Bi and Te in the related art.

So far, according to the present embodiment, it is possible to provide the thermoelectric conversion device having high conversion efficiency even at about room temperature (<200° C.)

### Third Embodiment

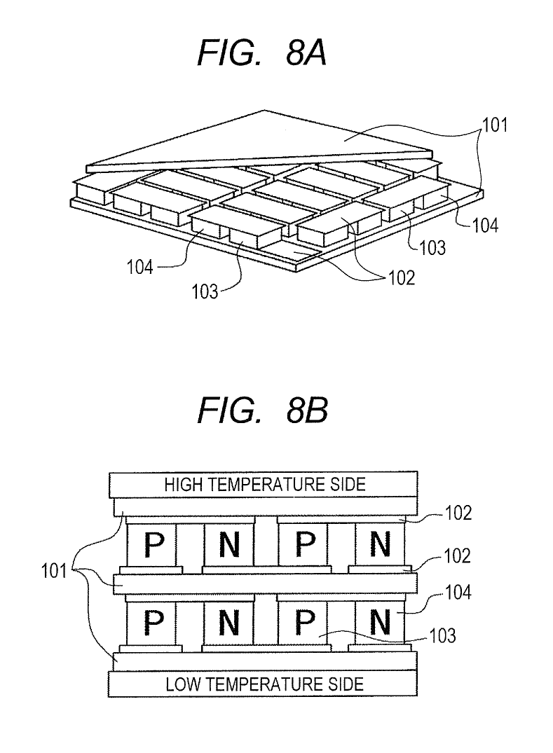

A third embodiment will be described by using FIGS. 8A and 8B. Further, a matter described in the first embodiment 1 or 2 but not described in the present embodiment can be applied to the present embodiment unless there is an unavoidable reason. FIGS. 8A and 8B are views illustrating a thermoelectric conversion module, FIG. 8A is a schematic whole perspective view (some portions are omitted) of a thermoelectric conversion module where a plurality of thermoelectric conversion devices having a π-type structure is arranged, and FIG. 8B illustrates a schematic cross-sectional view of a cascade-type thermoelectric conversion module. Reference numeral 101 represents an insulator layer (substrate).

A desired voltage and current may be obtained by connecting the desired number of n-type thermoelectric conversion devices of the second embodiment in series or in parallel as illustrated in FIGS. 8A and 8B. In the structures illustrated in FIGS. 8A and 8B, in the case where the hole carrier density is 1×10¹⁹ cm⁻³, thermoelectric conversion efficiency could be increased at about room temperature (<200° C.) to about three times the thermoelectric conversion efficiency of thermoelectric conversion device using Bi and Te in the related art, and the desired voltage and current could be effectively obtained. Particularly, the case of the structure illustrated in FIG. 8B may be applied to even the case where a temperature difference between a high temperature side and a low temperature side is large, or the case where temperature distributions are different.

So far, according to the present Example, it is possible to provide the thermoelectric conversion module having high conversion efficiency even at about room temperature (<200° C.). Further, the desired voltage and current can be obtained by arranging the thermoelectric conversion devices in series or in parallel.

Further, the present invention is not limited to the aforementioned embodiments, but includes various modifications. For example, the aforementioned embodiments are described in detail to easily understand the present invention but do not essentially have all constitutions described above. In addition, a portion of the constitution of an embodiment can be substituted by the constitution of another embodiment, and the constitution of another embodiment can be added to the constitution of the embodiment. Further, another constitution can be added to, removed from, and substituted for a portion of the constitution of each embodiment.

What is claimed is:

1. A thermoelectric conversion material having a pyrite structure, in which a composition is represented by Fe₁₋ₓMₓS_{2-y}T_{y}, element M is at least one kind of element selected from V, Cr, Mn, Zr, Nb, Mo, Hf, Ta, and W, element T is at least one kind of element selected from B, C, Al, Si, Ge, Sn, N, O, P, and Bi, x and y that are total composition values of the individual elements are each in the range of 0<x<0.5 and 0<y<1, and a conductive type is a p type.

2. The thermoelectric conversion material according to claim 1, wherein a main component of the thermoelectric conversion material is Fe₁₋ₓMₓS_{2-y}T_{y}, and the main components of Fe₁₋ₓMₓS_{2-y}T_{y} are Fe and S.

3. The thermoelectric conversion material according to claim 1, wherein a carrier density of the material whose composition is represented by Fe₁₋ₓMₓS_{2-y}T_{y} is in the range of 1×10¹⁸ to 1×10²² cm⁻³.

4. The thermoelectric conversion material according to claim 1, wherein the thermoelectric conversion material is used at a temperature of room temperature or more and 700° C. or less.

5. A thermoelectric conversion device including a thermoelectric conversion material layer, and a first upper electrode and a first lower electrode installed by interposing the thermoelectric conversion material layer therebetween,
wherein the thermoelectric conversion material layer is a p-type material layer having a pyrite structure whose composition is represented by FeS₂ and including at least a portion of Fe and S which is substituted by an addition element.

6. The thermoelectric conversion device according to claim 5, wherein a material composition of the p-type material layer where at least a portion of Fe and S is substituted by the addition element is represented by Fe₁₋ₓMₓS_{2-y}T_{y}, addition element M is at least one kind of element selected from V, Cr, Mn, Zr, Nb, Mo, Hf, Ta, and W, addition element T is at least one kind of element selected from B, C, N, O, Al, Si, P, Ge, Sn, and Bi, and x and y that are total composition values of the individual elements are each in the range of 0<x<0.5 and 0<y<1.

7. The thermoelectric conversion device according to claim 5, further comprising: another thermoelectric conversion material layer installed adjacent to the thermoelectric conversion material layer and having a conductive type different from the conductive type of the thermoelectric conversion material layer; and a second upper electrode and a second lower electrode installed by interposing the other thermoelectric conversion material layer therebetween, wherein the first upper electrode and the second upper electrode are electrically connected.

8. A thermoelectric conversion module having a plurality of types of thermoelectric conversion devices,
wherein a p-type thermoelectric conversion device of the plurality of thermoelectric conversion devices is formed by using the thermoelectric conversion material of claim 1.

9. A thermoelectric conversion module where a plurality of p-type thermoelectric conversion material layers spaced apart from each other and a plurality of n-type thermoelectric conversion material layers spaced apart from each other, which are arranged to be adjacent to each other, on an insulating substrate are connected in series,
wherein the p-type thermoelectric conversion material layer is a p-type material layer having a pyrite structure whose composition is represented by FeS₂ and including at least a portion of Fe and S which is substituted by an addition element.

10. The thermoelectric conversion module according to claim 9, wherein a material composition of the p-type material layer where at least a portion of Fe and S is substituted by the addition element is represented by Fe₁₋ₓMₓS_{2-y}T₂, addition element M is at least one kind of element selected from V, Cr, Mn, Zr, Nb, Mo, Hf, Ta, and W, addition element T is at least one kind of element selected from B, C, N, O, Al, Si, P, Ge, Sn, and Bi, and x and y that are total composition values of the individual elements are each in the range of 0<x<0.5 and 0<y<1.

11. The thermoelectric conversion module according to claim 9, wherein the insulating substrate on which the p-type thermoelectric conversion material layers and the n-type thermoelectric conversion material layers connected in series are arranged is laminated.
